(19) United States
(12) Patent Application Publication
(10) Pub. No.: US 2006/0207750 A1
(43) Pub. Date: Sep. 21, 2006

(54) Heat pipe with composite capillary wick structure

(75) Inventors: Chang-Shen Chang, Tu-Cheng (TW); Chao-Hao Wang, Tu-Cheng (TW)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology CO., LTD., Tu-Cheng City (TW)

(21) Appl. No.: 11/200,213

(22) Filed: Aug. 9, 2005

(30) Foreign Application Priority Data
Mar. 18, 2005 (TW) 94108395

(51) Int. Cl. H05K 7/20

(52) U.S. Cl. 165/104.26; 165/104.33; 361/700

(57) ABSTRACT

A heat pipe (20) includes a metal casing (22) having an evaporating section (70) and a condensing section (80). A first type of capillary wick (241) is provided in the evaporating section and a second type of capillary wick (242) is provided in the condensing section. The average capillary pore size of the second type of capillary wick is larger than that of the first type of capillary wick. The second type of capillary wick provides a low flow resistance to the liquid condensed in the condensing section to flow back and the first type of capillary wick develops a large capillary force to draw the liquid back to the evaporating section from the condensing section. Thus, the condensed liquid is brought back from the condensing section to the evaporating section in an accelerated manner.

### TECHNICAL FIELD

The present invention relates generally to a heat transfer apparatus, and more particularly to a heat pipe having composite capillary wick structure.

### BACKGROUND

As a heat transfer apparatus, heat pipes can transfer heat rapidly and therefore are widely used in various fields for heat dissipation purposes. Fox example, in electronic field, heat pipes are commonly applied to transfer heat from heat-generating electronic components, such as central processing units (CPUs), to heat dissipating devices, such as heat sinks, to thereby remove the heat away. A conventional heat pipe generally includes a sealed casing made of thermally conductive material and a working fluid contained in the casing. The working fluid is employed to carry heat from one end of the casing, typically called as “evaporating section”, to the other end of the casing, typically called as “condensing section”. Specifically, when the evaporating section of a heat pipe is thermally attached to a heat-generating electronic component, the working fluid receives heat from the electronic component and evaporates. Then, the generated vapor moves towards the condensing section of the heat pipe under the vapor pressure gradient between the two sections. In the condensing section, the vapor is condensed to liquid state by releasing its latent heat to, for example, a heat sink attached to the condensing section. Thus, the heat is removed away from the electronic component.

In order to rapidly return the condensed liquid back from the condensing section to the evaporating section to start a next cycling of evaporation and condensation, a capillary wick is generally provided in an inner surface of the casing in order to accelerate the return of the liquid. In particular, the liquid is drawn back to the evaporating section by a capillary force developed by the capillary wick. The capillary wick may be a plurality of fine grooves defined in its lengthwise direction of the casing, a fine-mesh wick, or a layer of sintered metal or ceramic powders. However, the capillary force derived from each type of these wicks is generally different, and meanwhile, the flow resistance provided by each type of wick may also be different. The general rule is that larger an average capillary pore size a wick has, smaller a capillary force it develops and lower a flow resistance it provides.

FIG. 6 shows an example of a conventional heat pipe. The heat pipe 10 includes a metal casing 12 and a singular uniform capillary wick 14 attached to an inner surface of the casing 12. The casing 12 includes an evaporating section 70 at one end and a condensing section 80 at the other end. A dielectric section 90, if desirable, may be provided between the evaporating and condensing sections 70, 80. The dielectric section 90 is typically used for transport of the generated vapor from the evaporating section 70 to the condensing section 80. The wick 14 is uniformly arranged against the inner surface of the casing 12 from its evaporating section 70 to its condensing section 80. However, this singular- and uniform-type wick 14 generally cannot provide optimal heat transfer effect for the heat pipe 10 because it cannot obtain simultaneously a large capillary force and a low flow resistance.

In view of the above-mentioned disadvantage of the conventional heat pipe, there is a need for a heat pipe having a good heat transfer effect.

### SUMMARY

The present invention relates to a heat pipe. In one embodiment, the heat pipe includes a metal casing having an evaporating section and a condensing section. A first type of capillary wick is provided in the evaporating section and a second type of capillary wick is provided in the condensing section. The average capillary pore size of the second type of capillary wick is larger than that of the first type of capillary wick.

As compared with the conventional heat pipe, the heat pipe in accordance with the present invention incorporates a composite capillary wick structure and therefore has many advantages. The second type of capillary wick provides a low flow resistance so that the liquid condensed in a condensing end of the condensing section, i.e., an extremity of the condensing section remote from the evaporating section can more easily flow through the condensing section to reach the evaporating section. Meanwhile, the first type of capillary wick develops a large capillary force to draw the liquid from the condensing section to flow through the evaporating section and return its original position, i.e., an extremity of the evaporating section remote from the condensing section. Thus, the condensed liquid is brought back from the condensing section to the evaporating section in an accelerated manner, thereby increasing the total heat transfer capacity of the heat pipe.

Other advantages and novel features of the present invention will become more apparent from the following detailed description of the preferred embodiment when taken in conjunction with the accompanying drawings, in which:

### BRIEF DESCRIPTION OF THE DRAWINGS

FIG. 1 is a longitudinal sectional view of a heat pipe in accordance with one embodiment of the present invention;

FIG. 2 is a cross-sectional view of the heat pipe of FIG. 1, taken along line II-II;

FIG. 3A is a cross-sectional view of the heat pipe of FIG. 1, taken along line III-III, by showing a first embodiment of the evaporating section;

FIG. 3B is similar to FIG. 3A by showing a second embodiment of the evaporating section;

FIG. 3C is similar to FIG. 3A by showing a third embodiment of the evaporating section;

FIG. 3D is similar to FIG. 3A by showing a fourth embodiment of the evaporating section;

FIG. 3E is similar to FIG. 3A by showing a fifth embodiment of the evaporating section;

FIG. 4 is a longitudinal sectional view of a heat pipe in accordance with another embodiment of the present invention;

FIG. 5 is a longitudinal sectional view of a heat pipe in accordance with a further embodiment of the present invention; and

FIG. 6 is a longitudinal sectional view of a conventional heat pipe.

### DETAILED DESCRIPTION OF THE PREFERRED EMBODIMENTS

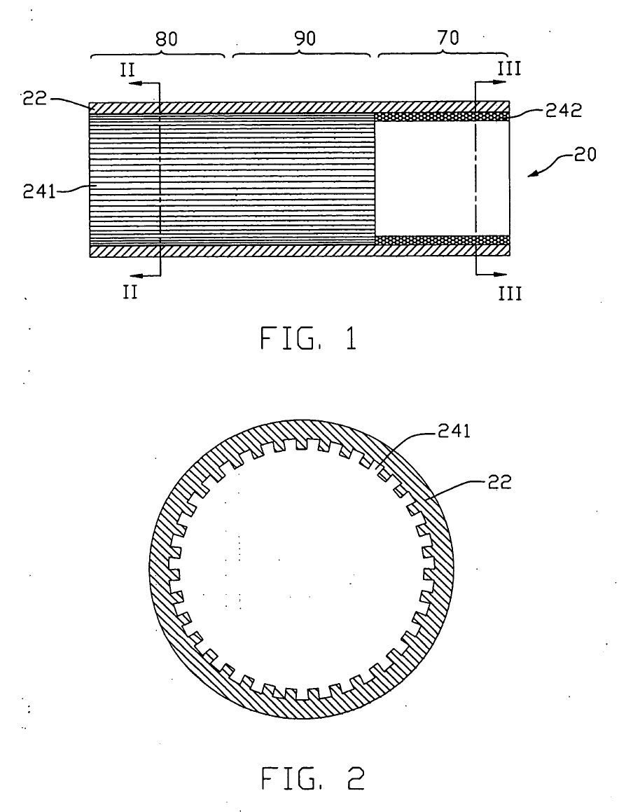

FIGS. 1-3A show a heat pipe 20 in accordance with one embodiment of the present invention. The heat pipe 20 includes a metal casing 22 made of high thermally conductive materials such as copper or copper alloys, a working fluid (not shown) contained in the casing 22 and a composite capillary wick (not labeled) arranged in an inner surface of the casing 22. In this embodiment, the casing 22 includes an evaporating section 70 at one end, a condensing section 80 at the other end and a dielectric section 90 arranged between the evaporating section 70 and the condensing section 80.

The working fluid functions as a heat carrier for transferring heat from the evaporating section 70 to the condensing section 80. In particular, the working fluid contained in the evaporating section 70 absorbs heat from heat source and evaporates, and then carries the heat to the condensing section 80 in the form of vapor. Then, the vapor releases its heat to ambient environment and is condensed back to liquid state. The condensed liquid is then brought back to the evaporating section 70 via the composite capillary wick.

The composite capillary wick includes a plurality of fine grooves 241 (hereinafter referring to as “groove-type wick”) defined in the condensing and dielectric sections 80, 90 and a layer of porous sintered powders 242 (hereinafter referring to as “sintered-type wick”) formed in the evaporating section 70 by sintering process. The grooves 241 extend in the lengthwise direction of the casing 22 and may be formed by mechanical machining. The sintering process typically involves steps of filling metal or ceramic powders into the casing 22 by using a mandrel to control the thickness of the sintered-type wick and sintering the powders under a high temperature to thereby form the sintered-type wick with porosity.

In this embodiment, the composite capillary wick has different types of capillary wick disposed in different sections of the heat pipe 20. The groove-type wick 241 has a relatively large average capillary pore size and therefore provides a relatively low flow resistance to the condensed liquid to flow therethrough, and meanwhile, the sintered-type wick 242 has a relatively small average capillary pore size and accordingly develops a relatively large capillary force to the liquid. As a result, the groove-type wick 241 reduces the flow resistance the condensed liquid encounters when flowing through the condensing and dielectric sections 80, 90, and the sintered-type wick 242 has a large capillary force and therefore the liquid is then rapidly drawn back to the evaporating section 70 from the dielectric section 90 as the liquid reaches to a position adjacent to the evaporating section 70. The condensed liquid is returned back from the condensing section 80 in an accelerated manner. After the condensed liquid is returned back to the evaporating section 70, a next phase-change cycling will then begin. Thus, as a whole, the cycling of the working fluid is accelerated and therefore the total heat transfer capacity of the heat pipe 20 is enhanced. On the other hand, the small-sized sintered-type wick 242 has a large surface area for contacting with the working fluid, and meanwhile maintains a large contact surface between the casing 22 and the wick 242, thereby facilitating the transport of heat from the heat-generating component into the heat pipe 20.

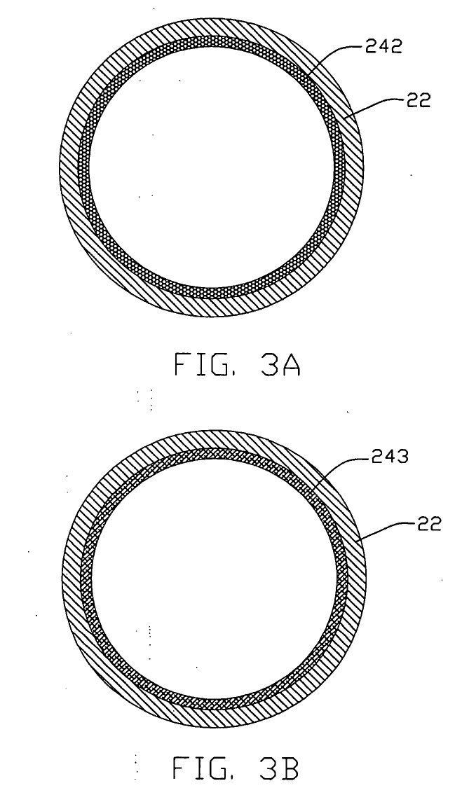

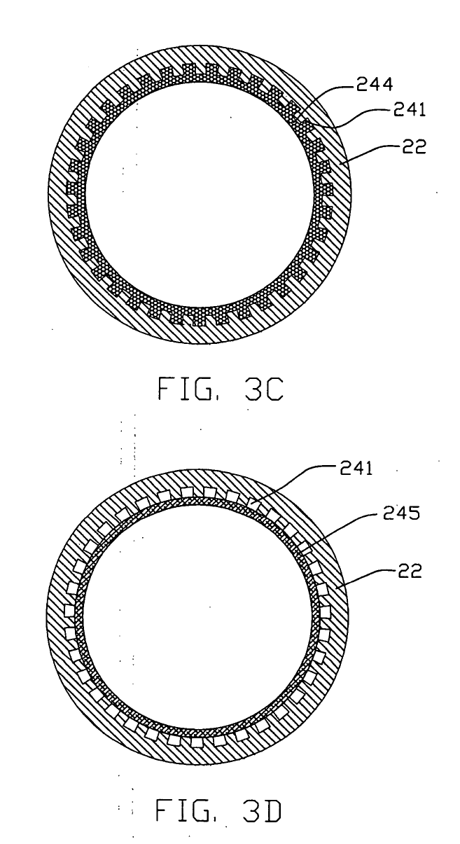

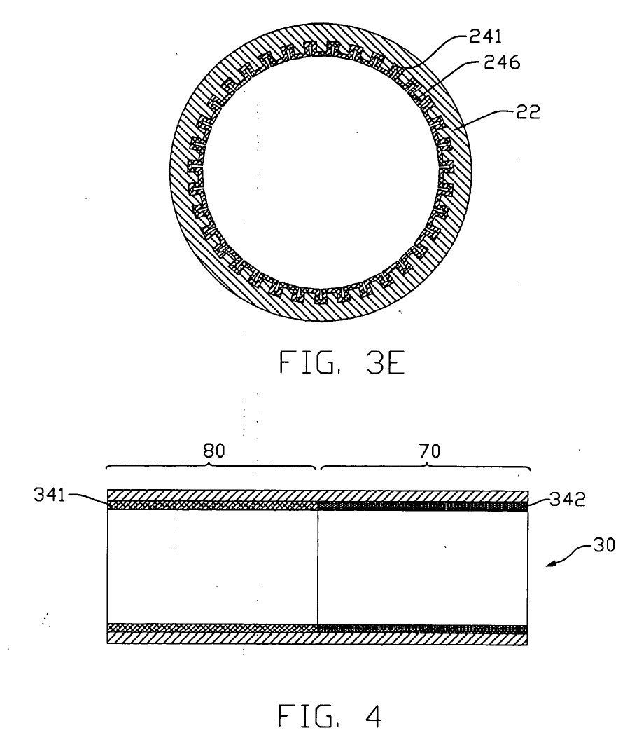

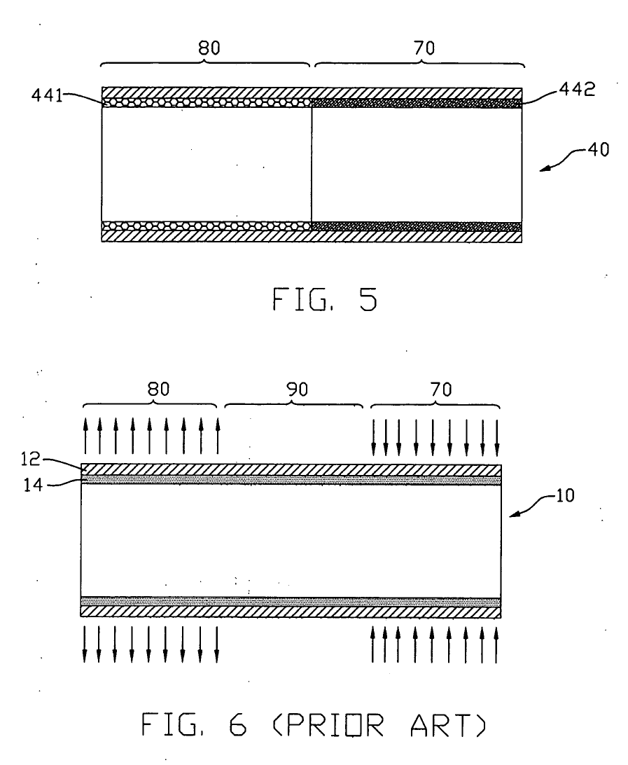

Except for the sintered-type wick 242, some other types of capillary wick can also be provided in the evaporating section 70 so long as they have a relatively small average pore size. For example, FIGS. 3B-3E illustrate some other capillary wicks which can be suitably applied to the evaporating section 70 of the heat pipe 20. As shown in FIG. 3B, a layer of fine mesh 243 (hereinafter referring to as “mesh-type wick”) is provided in the evaporating section 70 of the casing 22. The mesh-type wick 243 may be made by weaving metal wires or nylon wires. As illustrated in FIG. 3C, a composite wick structure composed of a sintered-type wick 244 and a plurality of fine grooves 241 is disclosed in the evaporating section 70 of casing 22, wherein the sintered-type wick 244 fills the grooves 241. With reference to FIG. 3D and FIG. 3E, a composite wick structure comprised of plural grooves 241 and a rounded fine-mesh 245 or a folded fine-mesh 246 is provided in the evaporating section 70 of the casing 22, respectively. The rounded fine-mesh 245 abuts against a plurality of protrusions (not labeled) each formed between every two adjacent grooves 241. The folded fine-mesh 246 is constructed in conformity with the shape of the grooves 241 so as to increase the contact surface between the wick 246 and the casing 22.

FIG. 4 illustrates a heat pipe 30 according to another embodiment of the present invention. The heat pipe 30 includes an evaporating section 70 at one end and a condensing section 80 at the other end. The heat pipe 30 incorporates a composite capillary wick which includes a mesh-type wick 341 arranged in the condensing section 80 and a sintered-type wick 342 arranged in the evaporating section 70. The average capillary pore size of the sintered-type wick 342 is smaller than that of the mesh-type wick 341. Thus, the large-sized mesh-type wick 341 provides a low resistance to the liquid condensed in a condensing end (not labeled) of the condensing section 80, i.e., an extremity of the condensing section 80 remote from the evaporating section 70 to flow through the condensing section 80 toward the evaporating section 70. Meanwhile, the small-sized sintered-type wick 342 develops a large capillary force to draw the condensed liquid from the condensing section 80 to flow through the evaporating section 70 and return its original position (not labeled), i.e., an extremity of the evaporating section 70 remote from the evaporating section 80. As a consequence, the condensed liquid is rapidly returned back to the evaporating section 70 from the condensing section 80.

FIG. 5 illustrates a heat pipe 40 according to a further embodiment of the present invention. A sintered-type wick 441 and a mesh-type wick 442 are provided in the condensing and evaporating sections 80, 70 of the heat pipe 40, respectively. The mesh-type wick 442 has a smaller average pore size than that of the sintered-type wick 441.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat pipe comprising:
a metal casing comprising a first section and a second section;
a first type of capillary wick provided in the first section; and
a second type of capillary wick provided in the second section, the average capillary pore size of the second type of capillary wick being larger than that of the first type of capillary wick.

2. The heat pipe of claim 1, wherein the second type of capillary wick is a plurality of fine grooves, and the first type of capillary wick is one of sintered metal powders and sintered ceramic powders.

3. The heat pipe of claim 1, wherein the second type of capillary wick is a plurality of fine grooves, and the first type of capillary wick is a fine mesh.

4. The heat pipe of claim 1, wherein the second type of capillary wick is a plurality of fine grooves, and the first type of capillary wick is a composite wick structure composed of fine grooves and one of sintered metal powders and sintered ceramic powders.

5. The heat pipe of claim 1, wherein the second type of capillary wick is a plurality of fine grooves, and the first type of capillary wick is a composite wick structure composed of fine grooves and a fine mesh.

6. The heat pipe of claim 5, wherein the fine mesh is folded to conform to the shape of the fine grooves so as to increase the contact surface between the metal casing and the fine mesh.

7. The heat pipe of claim 1, wherein the second type of capillary wick is a fine mesh, and the first type of capillary wick is one of sintered metal powers and sintered ceramic powders.

8. The heat pipe of claim 1, wherein the second type of capillary wick is one of sintered metal powders and sintered ceramic powders, and the first type of capillary wick is a fine mesh.

9. The heat pipe of claim 1, wherein the first section is an evaporating section of the metal casing and the second section is a condensing section of the metal casing.

10. The heat pipe of claim 9, wherein the metal casing further comprises a dielectric section provided between the evaporating section and the condensing section, the dielectric section having a capillary wick the same as the condensing section.

11. A heat pipe comprising:
a metal casing having an inner surface and defining an evaporating section for receiving heat and a condensing section for releasing heat;
a working fluid received in the metal casing and evaporated into vapor in the evaporating section and condensed into liquid in the condensing section; and
first capillary wick applied to the inner surface of the metal casing at the evaporating section and second capillary wick applied to the inner surface of the metal casing at the condensing section, the liquid condensed in the condensing section flowing to the evaporating section through the second and then the first capillary wick, the first capillary wick generating a larger capillary force for the liquid than the second capillary wick.

12. The heat pipe of claim 11, wherein the second capillary wick has a smaller flow resistance for the liquid than the first capillary wick.

13. The heat pipe of claim 12, wherein the first capillary wick is a sintered-type wick, and the second capillary wick is a groove-type wick.

14. The heat pipe of claim 12, wherein the first capillary wick is a combination of a groove-type wick and a sintered-type wick in the groove-type wick, and the second capillary wick is a groove-type wick.

15. The heat pipe of claim 12, wherein the first capillary wick is a combination of a groove-type wick and a mesh-type wick on the groove-type wick, and the second capillary wick is a groove-type wick.

16. The heat pipe of claim 15, wherein the mesh-type wick has a portion inserted into a groove of the groove-type wick of the first capillary wick.

17. The heat pipe of claim 12, wherein the first capillary wick is a mesh-type wick and the second capillary wick is a groove-type wick.

18. The heat pipe of claim 12, wherein the first capillary wick is a sintered-type wick and the second capillary wick is a mesh-type wick.

19. The heat pipe of claim 12, wherein the first capillary wick is a mesh-type wick and the second capillary wick is a sintered-type wick.

20. The heat pipe of claim 12, wherein the first capillary wick and the second capillary wick are formed of different wick structures.
